(19) United States
(12) Patent Application Publication
(10) Pub. No.: US 2015/0381118 A1
(43) Pub. Date: Dec. 31, 2015

(54) ELIMINATING SYSTEMATIC IMBALANCES AND REDUCING CIRCUIT PARAMETER VARIATIONS IN HIGH GAIN AMPLIFIERS

(71) Applicant: LSI Corporation, San Jose, CA (US)

(72) Inventors: Shyam S. Sivakumar, Mountain View, CA (US); Hiep T. Pham, Campbell, CA (US); Bradley Wright, Fort Collins, CO (US)

(21) Appl. No.: 14/317,642

(22) Filed: Jun. 27, 2014

(51) Int. Cl. H03F 1/30; H03G 3/30; H03F 3/16

(52) U.S. Cl. CPC H03F 1/301; H03F 3/16; H03G 3/30; H03F 2200/375

(57) ABSTRACT

Methods and devices for eliminating a systematic imbalance and reducing variations in circuit parameters for a high gain amplifies. A bias generator having a copy of an actual amplifier branch and an already generated bias voltage can be added to the amplifier to generate a bias voltage for a final current source at a current summing node so as to eliminate systematic imbalance in the bias current. A high impedance node can be wired in the bias generator such that all devices in the bias generator are in saturation across, for example, PVT (Process, Voltage and Temperature) corners in order to minimize tracking errors. A degeneration transistor similar to a differential pair element can be split into two equal halves.

### FIELD OF THE INVENTION

Embodiments are related to amplifier circuits and in particular to high gain amplifiers. Embodiments are also related to OTA (Operational Trans-conductance Amplifier) circuits and components. Embodiments are additionally related to techniques and circuits for eliminating systematic imbalances and reducing variations in circuit parameters for amplifier circuits and components.

### BACKGROUND

Amplifiers such as high gain amplifiers usually include one or more high impedance nodes controlled by two opposing bias currents such as, for example, a P current source and an N current sink. The bias generation circuits for P and N currents can introduce “systematic” imbalance (e.g., skews) in the currents. Such imbalances can cause the resulting device to go out of saturation at the circuit's “natural” quiescent point thereby causing large systematic offsets in the “natural” common model level at the high impedance nodes and also destroying the amplifier's gain. Conventionally, a negative feedback loop, referred to as a Common Mode Feedback (CMFB) loop can be employed to correct imbalances due to “random” statistical variations, which are typically unavoidable. Such a CMFB loop can be utilized to correct systematic imbalances by over-designing the loop. This approach, however, can result in a loss in additional power and area.

FIG. 1 illustrates a schematic circuit diagram of a conventional differential main amplifier 100 having active loads (ML1, ML2) and a tail current device MT. As shown in the configuration depicted in FIG. 1, a bias generation circuit mirrors a “golden” reference current IREF to N current IBN. Next, the IBN can be mirrored to obtain the P current IP for the active loads ML1, ML2 in the main amplifier 100. Further, IREF is also mirrored to the rail device MT in the main amplifier 100, which biases the differential pair devices (M1, M2) with the N current IN. This sets up the P and N currents in the main amplifier 100. Now, the outputs (Y1, Y2) are high impedance nodes and hence their common mode levels are poorly defined.

Further, the voltage headroom available for MT can be determined by a common mode level VCM at the input nodes (V1, V2). If MT “sees” a different drain-source voltage compared to MB2 in the IBN branch, IN becomes slightly different from IBN resulting in a mirroring error. Since IBN is mirrored to the P current IP, this error can be propagated and as a result IP and IN will not match perfectly at the summing nodes (Y1, Y2). To resolve this contention, the P or N devices in the main amplifier (M1, M2) are pushed into a triode region and (Y1, Y2) can be significantly different from X. One of the problems associated with the fully differential main amplifier 100 shown in FIG. 1 is that the bias circuit introduces a systematic skew and therefore, a natural quiescent point is not correct for proper operation.

FIG. 2 illustrates a schematic circuit diagram of the differential main amplifier 100 shown in FIG. 1 with a simple circuit modification 150. In the example shown in FIG. 1, M1R=M1=M2 is inserted in series and driven with the common mode level of the main amplifier inputs (VCM). Thereafter, the IBN branch encounters the same headroom for MB2 as the main amplifier's tail device MT. So, IN=IBN. Since IP is derived from the IBN branch, IP=IBN. As a result, IP=IN nominally by construction and the systematic skew is removed. Moreover, Y1, Y2=X and since the diode-connection holds MB3 in saturation, all devices in the main amplifiers are also held in saturation. In summary, the IBN branch tracks the main amplifier's operating conditions and generates IP accordingly.

Multi-stage feedback amplifiers typically utilize a differential pair as a key gain stage. Degeneration can be often used as a knob to control the gain of this stage. The closed loop dynamics (bandwidth/speed, phase margin/stability) are strongly dependent on a small-signal trans-conductance parameter of the gain stage. Consequently, wide variations in the stage parameter propagate as wide variations in the closed loop performance.

FIGS. 3-6 illustrate schematic circuit diagrams of a standard degeneration configuration 200 with respect to a differential pair (M1, M2), in accordance with the disclosed embodiments. Devices (M1, M2) constitute the differential pair each with trans-conductance gm. The boxed element represents an impedance network with conductance gd. Degeneration serves to reduce an effective trans-conductance (gm_effective) of an overall structure, by a “degeneration factor” and hence, often employed as a design knob to control the gain of the amplifier as shown below in equation (1):

$$gm\_effective = gm * Degeneration\_factor \\ where Degeneration\_factor = \frac{1}{1 + 0.5 * ( \frac{gm}{gd} )} \qquad ( 1 )$$

Degeneration can be commonly performed utilizing a resistor R as shown in FIG. 4 or a transistor MD biased at a fixed gate voltage VFIXED as shown in FIG. 5. The problem associated with gain control is that the differential pair element (M1, M2) and the degeneration element R or MD do not track each other and the degeneration factor shows significant variation over process, voltage, and temperature (PVT) and common mode. So, the effective gm (and hence gain) exhibits more variation than the un-degenerated version. While degenerating with the transistor MD (at a fixed gate bias) tracks better than the resistor R, the degeneration factor can vary substantially if the devices are operating near sub-threshold region (low gate drives).

Enhanced tracking can be achieved through the configuration depicted in FIG. 6. Here, the degeneration transistor MD can be biased at the common mode (average) voltage VCM at the differential pair inputs (V1, V2). At balanced conditions and no mismatch, (M1, M2) are in saturation with gate drive Vov and MD can be in triode with same gate drive Vov and drain-source voltage Vds(=0). Further, small-signal parameters can be defined as shown below in equations (2) and (3) below

gm=gm(M1,M2) in saturation=trans-conductance of M1,M2; (2)

gd=gd(DD) with Vds near zero=conductance of MD in triode (3)

Assuming a square law model for the transistors, currents in (M1, M2, MD) can be expressed as shown below in equations (4) and (5) below:

$$\begin{matrix}I ( M 1 , M 2 ) = 0.5 * K * \frac{W ( M 1 , M 2 )}{L ( M 1 , M 2 )} * Vov * Vov & ( 4 ) \\ I ( M D ) = K * \frac{W ( M D )}{L ( M D )} * ( Vov - 0.5 * vds ) * vds & ( 5 )\end{matrix}$$

where K represents model constant, W( ) and L( ) represents width and lengths of respective transistors. Using partial derivatives and applying Vds=0, the small-signal parameters can be defined as shown below in equations (6) and (7):

$$\begin{matrix}gm = K * \frac{W ( M 1 , M 2 )}{L ( M 1 , M 2 )} * Vov & ( 6 ) \\ gd = K * \frac{W ( M D )}{L ( M D )} * Vov & ( 7 )\end{matrix}$$

Assuming M1, M2, and MD are similar type of devices with same lengths, we have the following, as shown in equations (8) and (9):

$$\begin{matrix}\frac{gm}{gd} = \frac{W ( M 1 , M 2 )}{W ( MD )} = width\_ratio & ( 8 ) \\ Degeneration\_factor = \frac{1}{( 1 + 0.5 * \frac{gm}{gd} )} & ( 9 )\end{matrix}$$

Since the degeneration factor is a function of the ratio “gm/gd”, it is based only on a width ratio which makes it immune to PVT and common mode variations. But, the common mode voltage (VCM), which is the average of the two input voltages, (V1, V2) may not be a readily available node for connecting to the degeneration device. It would be desirable to obtain the same effect, for example, between the circuit configurations shown in FIGS. 5-6 without needing the VCM, particularly because some components may not have access to the VCM.

### SUMMARY

The following summary is provided to facilitate an understanding of some of the innovative features unique to the disclosed embodiments and is not intended to be a full description. A full appreciation of the various aspects of the embodiments disclosed herein can be gained by taking the entire specification, claims, drawings, and abstract as a whole.

It is, therefore, one aspect of the disclosed embodiments to provide for an improved operational trans-conductance amplifier.

It is another aspect of the disclosed embodiments to provide for improved methods, devices, and circuits for eliminating systematic imbalances in operating currents and consequent impact on a CMFB (Common Mode Feedback) loop design.

It is yet another aspect of the disclosed embodiments to provide for improved methods, devices, and circuits for reducing variations in closed loop dynamics by reducing variations in small-signal trans-conductance of particular circuit stages when used with degeneration.

The aforementioned aspects and other objectives and advantages can now be achieved as described herein. Methods, devices, and circuits are disclosed for eliminating systematic imbalance and reducing variations in circuit parameters for high gain amplifier. A bias generator having a copy of an actual amplifier branch and an already generated bias voltage can be added to the amplifier to generate a bias voltage for a final current source at a current summing node and to eliminate systematic imbalance in the bias current. A high impedance node can be wired in the bias generator such that all devices in the bias generator are in saturation across PVT (Process, Voltage, and Temperature) corners in order to minimize tracking errors. A degeneration transistor similar to a differential pair element can be split into two equal halves. Gates of one-half of the degeneration device can be driven with a positive input and the other half with a negative input to achieve an averaging effect and retain a degeneration feature while eliminating systematic and random variations.

The bias generator with the high impedance node can generate a last bias at the current summation node so that all non-idealities of the real circuit are naturally tracked and the P-N current balance can be guaranteed by design. A sum of P currents is always equal to the sum of N currents by construction and the final current is always generated from other currents thereby ensuring there are no systematic imbalances in bias currents.

The P and N currents can be tracked always with respect to each other regardless of the absolute mirroring accuracy with respect to a master reference current. The device controlling the high impedance nodes are also held in saturation across PVT so that a CMFB correction loop always functions in a high gain region while minimizing tracking errors. The CMFB correction current can be lowered since it requires compensation only for random mismatches so that a quiescent current in the circuit are not significantly altered from a design target.

The bias generator with the high impedance node can be utilized to generate bias currents for the first stage in a two-stage OTA operating in a switched capacitor feedback loop for an ADC.

The first stage is a folded-cascoded configuration comprising a NMOS differential pair as a gain element and a PMOS and NMOS active load. The differential pair's tail current and a NMOS active current load are both cascoded. The CMFB loop can be employed to control the output common model level.

The splitting of the degeneration transistors implements averaging in the small signal sense without altering differential operation and reduces Monte-Carlo variations in the degeneration factor. The ratio-metric degeneration scheme also reduces variation in a small-signal effective trans-conductance of the stage. Since the closed loop dynamics are strongly dependent on the effective stage trans-conductance, this translates to smaller variations in a loop bandwidth (e.g., speed) and a loop phase margin (e.g., stability). The modified degeneration transistors can be utilized in the CMFB loop for OTA in the ADC in a single-ended configuration and to degenerate the differential pair inside the CMFB amplifier.

### BRIEF DESCRIPTION OF THE FIGURES

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a schematic circuit diagram of a prior art differential main amplifier having active loads and a tail current device, presented herein for general illustrative and background purposes only;

FIG. 2 illustrates a prior art schematic circuit diagram of the differential main amplifier with simple modification, in accordance with the disclosed embodiments;

FIGS. 3-6 illustrate prior art schematic circuit diagrams of a differential pair configuration with a standard degeneration configuration, in accordance with the disclosed embodiments;

FIG. 7 illustrates a high level flow chart of operations illustrating logical operational steps of method for eliminating systematic imbalances and reducing variation of circuit parameters in a high gain amplifier, in accordance with a preferred embodiment;

FIG. 8 illustrates a schematic circuit diagram of a folded cascade amplifier topology having a copy of an actual amplifier branch and already generated bias voltage and a high impedance node, in accordance with an alternative embodiment;

FIG. 9 illustrates a circuit diagram of the differential pair with a modified degeneration configuration, in accordance with an alternative embodiment;

FIGS. 10-12 illustrate circuit diagrams of a single-ended component/operation with the modified degeneration configuration, in accordance with alternative embodiments: and

FIG. 13 is an illustration of how the modification(s) discussed herein assist in reducing variations due to offset, in accordance with one possible embodiment.

### DETAILED DESCRIPTION

The particular values and configurations discussed in these non-limiting examples can be varied and are cited merely to illustrate at least one embodiment and are not intended to limit the scope thereof.

The embodiments will now be described more fully hereinafter with reference to the accompanying drawings, in which illustrative embodiments of the invention are shown. The embodiments disclosed herein can be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout. As used herein, the term “and/or” includes any and all combinations of one or more of the associated listed items.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

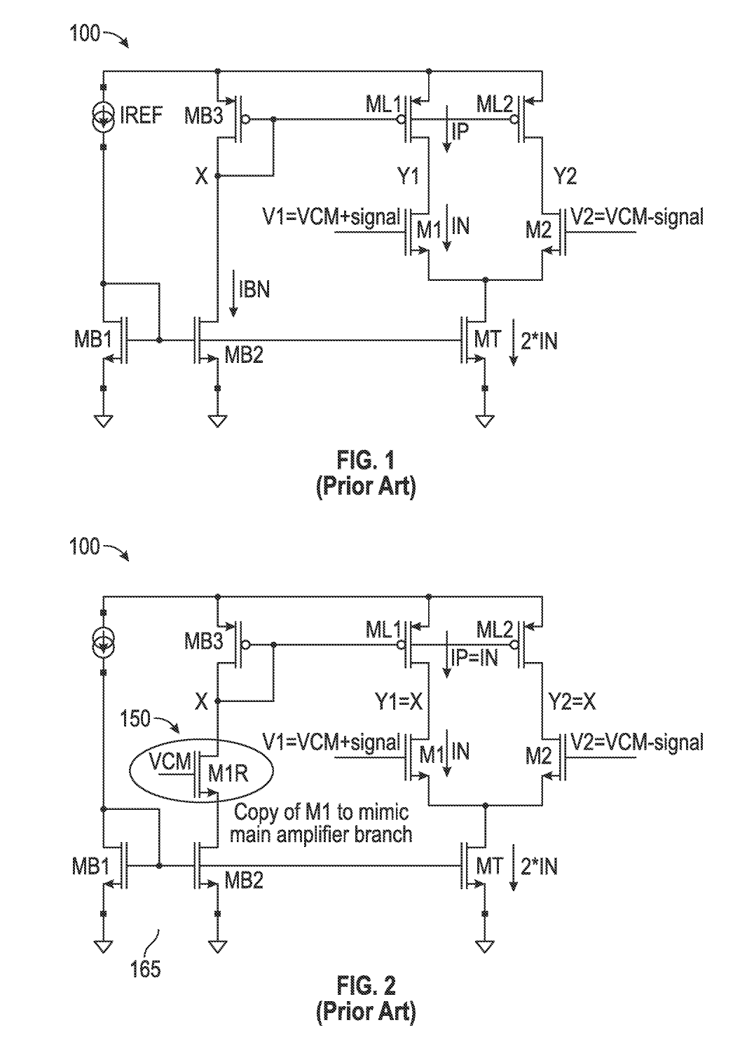

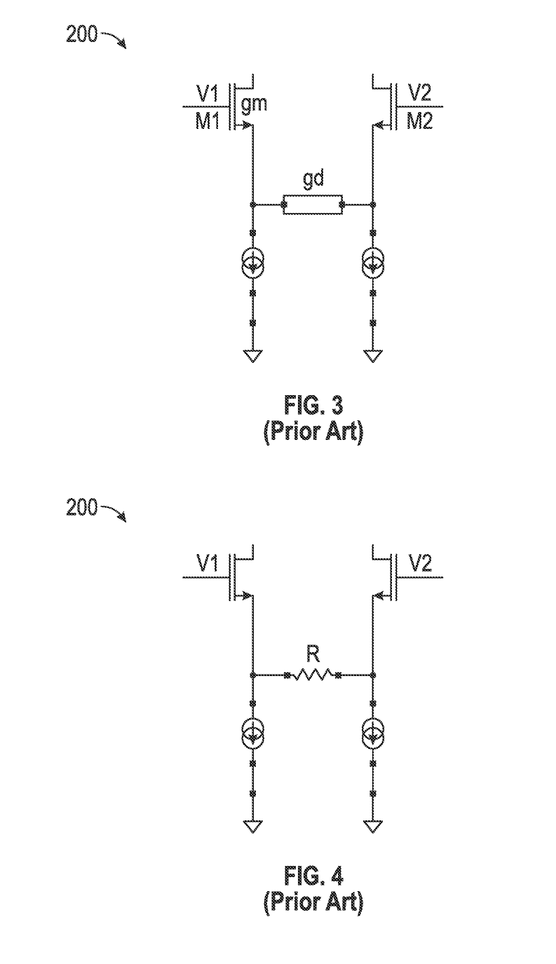

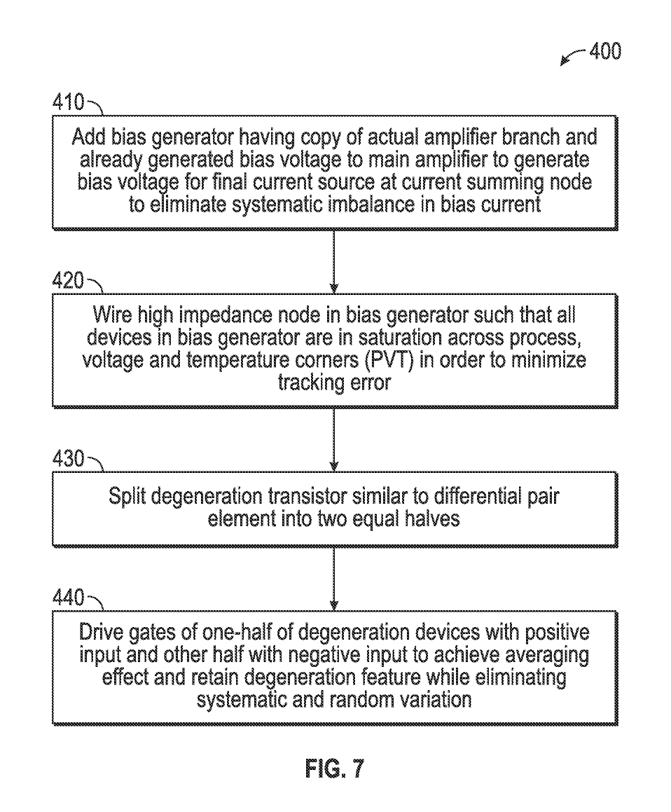

FIG. 7 illustrates a high level flow chart of operations illustrating logical operational steps of a method 400 for eliminating systematic imbalances and reducing variation of circuit parameters in a high gain amplifier, in accordance with a preferred embodiment. Note that in FIGS. 1-13, identical or similar blocks are generally indicated by identical reference numerals. It can be appreciated, however, that varying embodiments may be represented by different features of FIGS. 1-13. It can also be appreciated that the steps or logical operations shown in FIG. 7 are not necessarily sequential. That is, for example, the operations shown at blocks 410, 420, 430, and 440 can be re-ordered or performed in a different sequence.

As indicated at block 410, a bias generator having a copy of an actual amplifier branch and an already generated bias voltage 505 can be added to an amplifier 500 to generate a bias voltage for a final current source at a current summing node to eliminate systematic imbalance in bias current. Thereafter, as illustrated at block 420, a node 510 can be wired in the bias generator 505 such that all devices in the bias generator 505 are in saturation across PVT corners in order to minimize tracking errors. Then, as depicted at block 430, a degeneration transistor similar to a differential pair element can be split into two equal halves 610. Gates of one-half of the degeneration device can be driven with a positive input 605 and the other half with a negative input 615 to achieve an averaging effect while retaining a degeneration feature and eliminating systematic and random variations, as described at block 440.

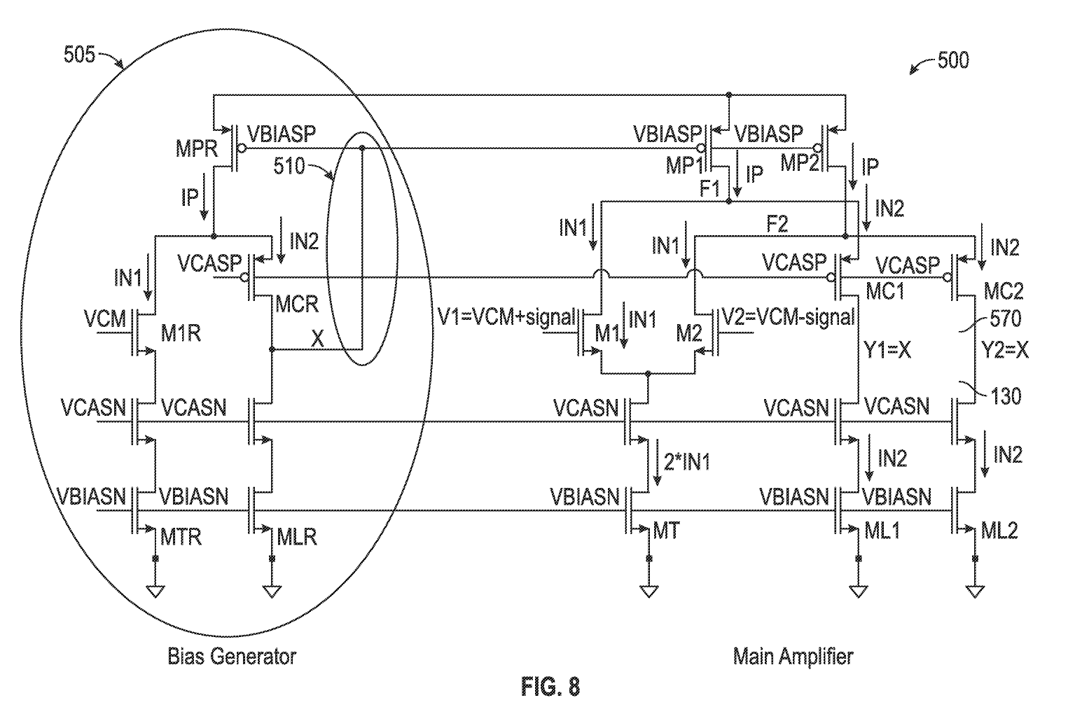

FIG. 8 illustrates a schematic circuit diagram of the folded cascode amplifier topology 500 having a copy of the actual amplifier branch and already generated bias voltage 505 and the node 510, in accordance with an embodiment. The folded cascode amplifier topology 500 includes a main amplifier comprising an NMOS differential pair (M1, M2) with a cascaded tail current MT, cascaded NMOS active loads (ML1, ML2), and P current sources (MP1, MP2). (MC1, MC2) form the folded cascode devices in a signal path. The folded cascode amplifier topology 500 further includes high impedance output nodes (Y1, Y2). In general, the circuit must obey current summation, i.e., Kirchhoff's Current Law (KCL) at a folded nodes (F1, F2) as IP=IN1+IN2. If there is a systematic skew in a generation of (IP, IN1, IN2), then the circuit 500 adjusts by pushing either a P or N device into triode to satisfy the current summation rule.

The folded cascode amplifier topology 500 includes an exact copy of the main amplifier 500 with the folding structure and three previously generated biases VBIASN, VCASN, VCASP to generate a fourth and final bias VBIASP for a P current as indicated by arrow 505. Specifically, transistor stacks MTR, M1R, MLR, MCR, and MPR can replicate the transistor stacks MT, M1, ML1, MC1, and MP1 from a half section of the main amplifier 500. Moreover, a matching PFET MPR can be diode-connected to node X to ensure that P devices in the bias generator 505 are in saturation for the generated VBIASP.

Since the bias generator 505 naturally satisfies the current summation rule with all its devices in saturation and all the currents are identically mirrored, the main amplifier 500 also reflects a similar behavior. As a result, an output node (Y1, Y2) “naturally” sits at a same voltage as X and the main amplifier 500 has all its currents in saturation at its quiescent point even before CMFB is applied. Note that the identical branch of the actual circuit that includes a current summation node is used to generate the last bias voltage as indicated by arrow 505, so that all non-idealities of the real circuit are naturally tracked and P-N current balance is guaranteed by design.

The high impedance node X shown in FIG. 8 can be wired in a diode-connected configuration to the gate of MPR (node VBIASP) to form the node 510 as shown in the bias generator 505 such that all devices in the bias generator are in saturation across PVT. The P and N currents will always track each other regardless of absolute mirroring accuracy with respect to a master reference current. The final current is always generated from other currents. A sum of P currents is always equal to the sum of N currents by construction thereby ensuring there are no systematic imbalances in bias currents. The real circuit tracks the bias generator 505 and devices controlling node 510 are held in saturation across PVT so that CMFB correction loop always works in its high gain region minimizing tracking error and CMFB correction current can be lowered since it only needs to compensate for random mismatches. So, a quiescent current in the circuit 500 are not significantly altered from their design targets.

The copy of the actual amplifier branch and already generated bias voltage 505 and the node 510 generates bias currents for a first stage in a two-stage OTA operating in a switched capacitor feedback loop for an ADC. The first stage can be used in a folded-cascode configuration comprising the NMOS differential pair as gain element and PMOS and NMOS active loads. The differential pair's current and the NMOS active current load are both cascoded. The CMFB loop can be employed to control the output common model level.

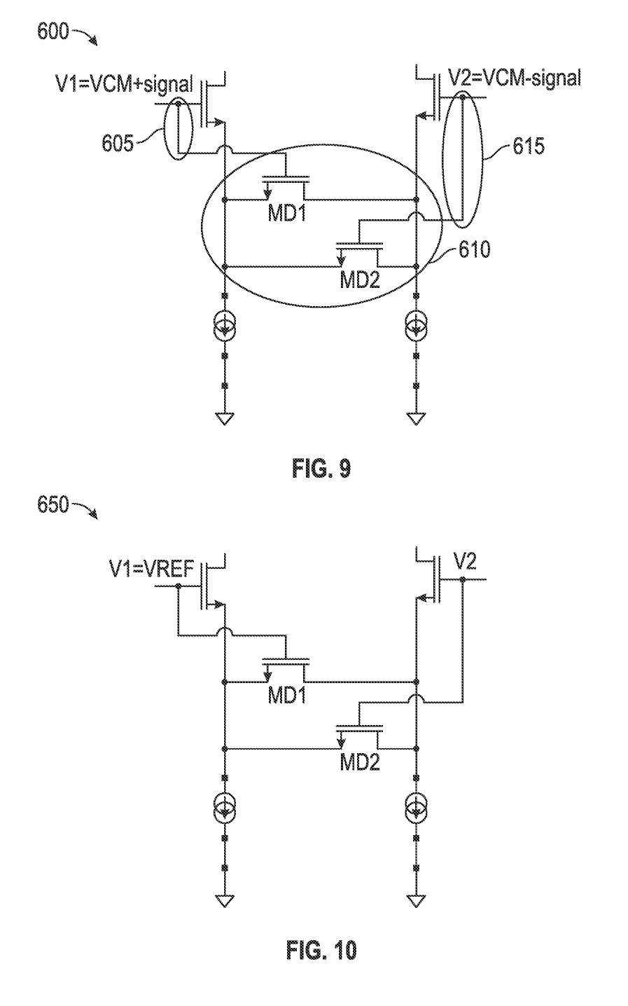

FIG. 9 illustrates a schematic circuit diagram of a differential pair 600 with a modified degeneration configuration 605, 610, and 615, in accordance with an alternative embodiment. The degeneration transistor MD can be split into two equal half-width devices MD1 and MD2, as indicated by arrow 610. Gate of MD1 is wired to input node V1, as indicated by arrow 605. Gate of MD2 is wired to the other input node V2, as indicated by arrow 615. This re-wiring implements an averaging in a small-signal sense without altering a differential operation. Such as, if V1 goes low and V2 goes high, MD1 becomes weaker and MD2 becomes stronger by roughly with a same amount.

Because the two halves are in parallel, a total additive strength (conductance) remains constant. On the other hand, if both V1 and V2 move up or down, both MD1 and MD2 see no change across its terminals and hence total additive conductance remains the same in the presence of such common mode changes as well. In other words, the total conductance is invariant to both differential and common mode perturbations, in a small-signal sense. Further, as shown earlier, since the differential pair devices 600 and degeneration devices 605 are of the similar type biased at the same gate drive, the degeneration factor is set by a width ratio and hence immune to PVT and input common mode variations. The modified degeneration configuration 605, 610, and 615 achieves an averaging effect and a natural tracking of certain key small-signal parameters of a stage across PVT.

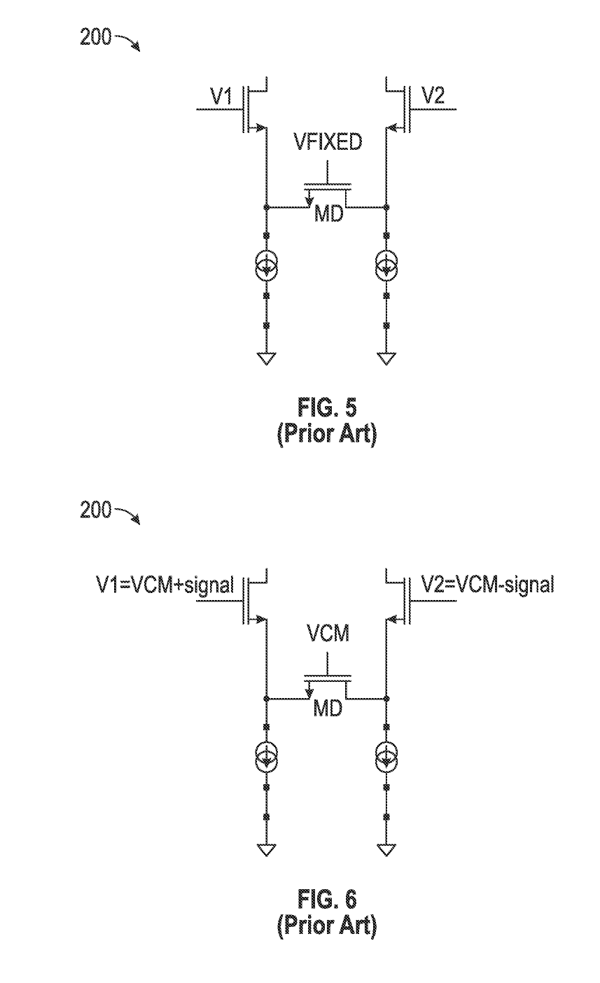

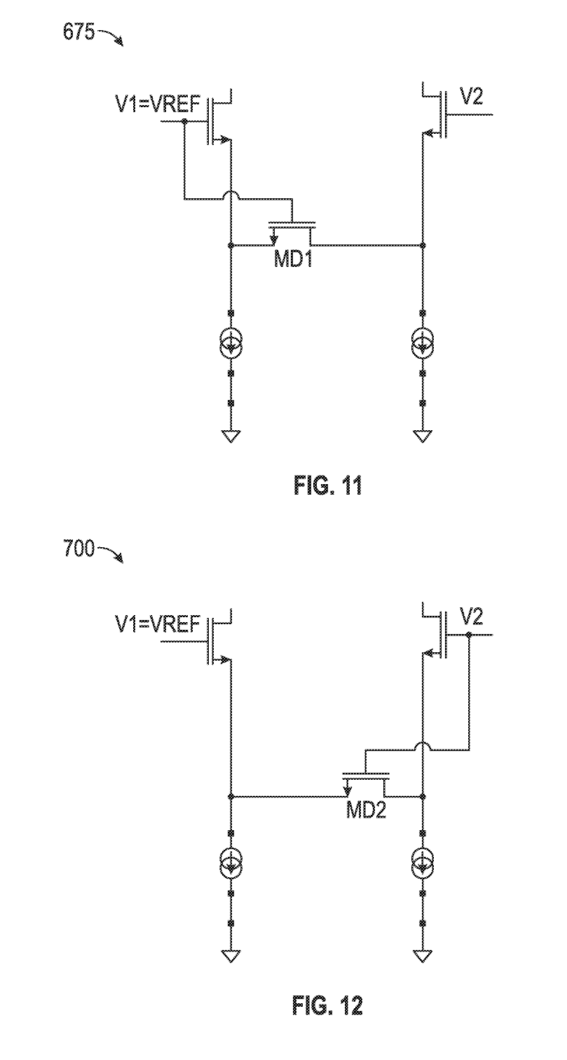

FIGS. 10-12 illustrate a circuit diagram of a single-ended component 650, 675, and 700 with the modified degeneration configuration 605, 610, and 615, in accordance with alternative embodiments. FIGS. 10-12 show three single-ended configurations 650, 675, and 700 by tracking between the amplifying device and the degeneration device. FIG. 10 illustrates a similar concept and benefits incurred in FIG. 9 when applied to a single-ended usage scenario. FIGS. 11-12 depict situations where the gate of the degeneration device 675 and 700 can be connected to only one of the two inputs. Even though these two cases do not use both inputs, they realize a significant reduction in PVT variations compared to the standard topologies depicted in FIGS. 3-5 due to the ratiometric tracking between the amplifying device and the degeneration device.

The modified degeneration configurations 605, 610, and 615 reduce Monte-Carlo variations as a statistical matching is significantly better because it is transistor-to-transistor matching which can be highly correlated rather than transistor-to-resistor which is uncorrelated. Further, the “average” gate drive for the differential pair devices tracks the “average” gate drive for the degeneration devices. This has the benefits of reducing variations in the degeneration factor due to certain statistical effects like DC offsets. For example, consider the degenerated amplifier used as the first stage in the single-ended configuration 650, 675, and 700 under negative feedback, a very common usage scenario. Under the presence of statistical mismatch, it can quiesce at its offset-compensated balance point.

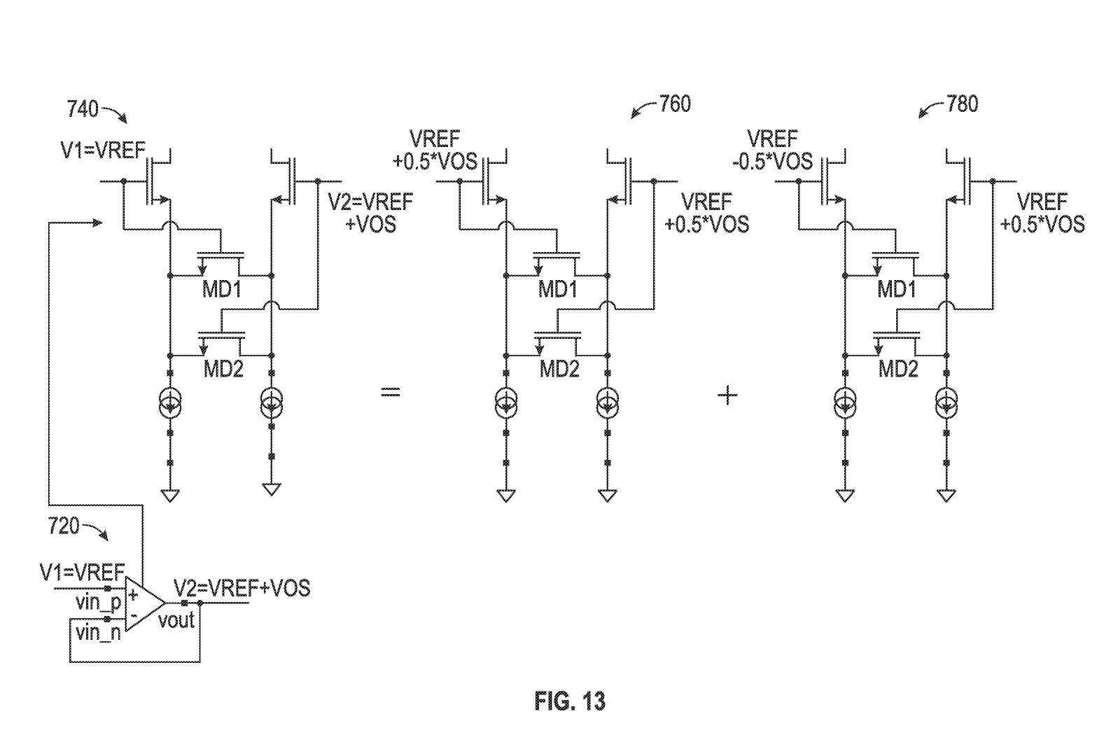

FIG. 13 is an illustration of how the modification(s) discussed herein assist in reducing variations due to offset, in accordance with one possible embodiment. The configuration shown in FIG. 13 is not actually a circuit diagram, but a conceptual illustration showing how the single-ended mode 740, when used inside a unity feedback configuration 720 can be viewed as a superposition of a common mode component 760 and a differential mode component 780 having the modified degeneration configurations 605, 610, and 615. FIG. 13 is thus an instructional diagram for analysis purposes rather than an actual circuit diagram.

As shown in FIG. 13, the unity feedback usage 720 can include a VREF that represents fixed reference input and V2=VREF+VOS represents other input, with VOS being the input-referred offset. This DC offset introduces a perturbation to the single ended amplifier's operating point, as depicted in the inset 740. As mentioned before, this perturbation can be viewed as a superposition of common-mode component 760 and differential mode component 780.

If the degeneration devices have a fixed gate bias (e.g., VREF used as its gate bias), then the DC offset would cause a common mode perturbation as shown in the common mode component 760, thereby altering their gate drives and hence the degeneration factor. If degeneration configurations 605, 610, and 615 are used as shown in 760, however, the structure becomes invariant to common mode variations (e.g., gate drive for both the differential pair devices and the degeneration devices in configuration 605, 610, and 615 are equal in common mode component 760), and the sensitivity to the DC offset is substantially reduced. Note that the differential component 780 in the presence of DC offset does not affect the degeneration factor owing to its symmetry and fully differential nature. As a result, the main source of residual variation in the degeneration factor is the local mismatch between the devices.

In summary, using the same device type in the gain and degeneration elements in configurations 605, 610, and 615 can create a virtual common mode bias on or at the degeneration devices due to the inherent averaging that occurs, thereby realizing the equivalent effect of the configuration shown in FIG. 6 without requiring an actual connection to a physical VCM node, which may not be available or usable. This feature enables both PVT and common mode tracking of the degeneration factor. Further, the degeneration configurations 605, 610, and 615 also can reduce Monte-Carlo variations in the degeneration factor.

Thus, the ratio-metric degeneration configurations 605, 610, and 615 can reduce variations in the small-signal effective trans-conductance of the stage. Because the closed loop dynamics are strongly dependent on the stage trans-conductance, this translates to smaller variations in the loop bandwidth (speed) and loop phase (stability). The modified degeneration configurations 605, 610, and 615 can be utilized in the CMFB loop for the OTA in the ADC in the single-ended configuration 650, 675, and 700. Specifically, the differential pair inside the CMFB amplifier can be degenerated using the modified degeneration configurations 605, 610, and 615.

The modified degeneration configuration 605, 610, and 615 achieves an averaging effect and a natural tracking of certain key small-signal parameters of the stage across PVT. This enables to retain the degeneration feature while substantially reducing both systematic and random (Monte-Carlo) variations of these small-signal parameters of the stage without any area or power penalty.

It will be appreciated that variations of the above-disclosed and other features and functions, or alternatives thereof, may be desirably combined into many other different systems or applications. Also, that various presently unforeseen or unanticipated alternatives, modifications, variations or improvements therein may be subsequently made by those skilled in the art which are also intended to be encompassed by the following claims.

1. A method for reducing variations and mismatch in circuit parameters of an amplifier circuit, said method comprising:
removing an offset between at least one current source and at least one current sink in an amplifier circuit via a bias generation component; and
ensuring that all components associated with said amplifier circuit are in saturation at a quiescent point across varying operating conditions of said amplifier circuit so as to relax the design of feedback loops employed to regulate common mode levels at high impedance nodes within said amplifier circuit.

2. The method of claim 1 further comprising:
configuring said amplifier circuit to include at least one current summing node; and
employing a copy of a branch of said amplifier circuit and at least one previously generated bias voltage to generate a bias voltage for a final current source at said at least one current summing node.

3. The method of claim 1 further comprising wiring a high impedance node in a bias generator of said amplifier circuit such that all devices in said bias generator are in saturation across process, voltage, and temperature.

4. The method of claim 1 further comprising matching a copy of at least one branch of said amplifier circuit to a main amplifier of said amplifier circuit.

5. The method of claim 1 further comprising configuring said amplifier circuit such that P current sources and N current sinks within said amplifier circuit track one another regardless of absolute mirroring accuracy with respect to a master reference circuit.

6. A degeneration method for use in reducing variations in amplifier circuits, said method comprising:
configuring an amplifier circuit to include at least one gain stage that employs degeneration with a degeneration factor; and
reducing a variation in transconductance of said at least one gain stage by rendering said degeneration factor invariant to changes in operating conditions of said amplifier circuit, such that a resulting reduction in gain variation translates to a reduced spread in system level parameters.

7. The method of claim 6 further comprising configuring said amplifier circuit with a tight spread in circuit parameters including at least bandwidth and phase shifts associated with said amplifier circuit.

8. The method of claim 6 further comprising incorporating said at least one gain stage into a closed loop amplifier circuit within said amplifier circuit, so as to reduce gain variation thereof.

9. The method of claim 6 further comprising configuring said amplifier circuit to include transistors of the same type as differential pair elements of said at least one gain stage for degeneration.

10. The method of claim 6 further comprising configuring said at least one gain stage to include at least one degeneration device that is split into two equal halves.

11. The method of claim 10 further comprising a gate of one half of said two equal halves of said at least one degeneration device with a positive input and the other half of said two equal halves of said at least one degeneration device with a negative input.

12. An apparatus for reducing variations and mismatch in circuit parameters of an amplifier circuit, said apparatus comprising:
at least one current source and at least one current sink in an amplifier circuit, wherein an offset between said at least one current source and said at least one current sink in said amplifier circuit is removed via a bias generation component; and
wherein all components associated with said amplifier circuit are in saturation at a quiescent point across varying operating conditions of said amplifier circuit so as to minimize feedback loops employed to regulate common mode levels at high impedance nodes within said amplifier circuit.

13. The apparatus of claim 12 wherein said amplifier circuit further comprises:
at least one current summing node; and
wherein a copy of a branch of said amplifier circuit and at least one previously generated bias voltage are employed by said amplifier circuit to generate a bias voltage for a final current source at said at least one current summing node.

14. The apparatus of claim 12 further comprising a high impedance node wired in a bias generator of said amplifier circuit such that all devices in said bias generator are in saturation across process, voltage, and temperature.

15. The apparatus of claim 12 wherein a copy of at least one branch of said amplifier circuit is matched to a main amplifier of said amplifier circuit.

16. The apparatus of claim 12 wherein said amplifier circuit is configured such that P current sources and N current sinks within said amplifier circuit track one another regardless of absolute mirroring accuracy with respect to a master reference circuit.

17. An apparatus for reducing variations in amplifier circuits, said apparatus comprising:
an amplifier circuit comprising at least one gain stage that employs degeneration with a degeneration factor, wherein a variation in transconductance of said at least one gain stage is reduced by rendering said degeneration factor invariant to changes in operation conditions of said amplifier circuit, such that a resulting reduction in gain variation translates to a reduced spread in system level parameters.

18. The apparatus of claim 17 wherein said amplifier circuit is configured with a tight spread in circuit parameters including at least bandwidth and phase shifts associated with said amplifier circuit.

19. The apparatus of claim 17 wherein said at least one gain stage is incorporated into a closed loop amplifier circuit within said amplifier circuit, so as to reduce gain variation thereof.

20. The apparatus of claim 17 wherein said amplifier circuit further comprises transistors of the same type as differential pair elements of said at least one gain stage for degeneration.
